(19) United States
(12) Patent Application Publication
(10) Pub. No.: US 2023/0268468 A1
(43) Pub. Date: Aug. 24, 2023

(54) LIGHT EMITTING SEMICONDUCTOR CHIP AND METHOD FOR MANUFACTURING A PLURALITY OF LIGHT EMITTING SEMICONDUCTOR CHIPS

(71) Applicant: OSRAM Opto Semiconductors GmbH, Regensburg (DE)

(72) Inventor: David O'BRIEN, Portland, OR (US)

(21) Appl. No.: 17/677,152

(22) Filed: Feb. 22, 2022

(51) Int. Cl. H01L 33/50; H01L 25/075; H01L 33/00

(52) U.S. Cl. CPC H01L 33/504; H01L 25/0753; H01L 33/005; H01L 2933/0041

(57) ABSTRACT

A light emitting semiconductor chip comprising the following features is provided: a chip region comprising an epitaxial semiconductor layer stack with an active zone configured to generate electromagnetic radiation of a first wavelength range during operation, a wavelength conversion element converting the electromagnetic radiation of the first wavelength range in electromagnetic radiation of a second wavelength range, wherein the wavelength conversion element is arranged on or over a main surface of the chip region, and the wavelength conversion element covers only a part of the main surface of the chip region, while a further part of the main surface of the chip region is free of the wavelength conversion element. Further, a method for manufacturing a plurality of light emitting semiconductor chip is provided.

A light emitting semiconductor chip and a method for manufacturing a plurality of light emitting semiconductor chip are provided.

A light emitting semiconductor chip emitting electromagnetic radiation having a color locus being improved adapted to a predetermined value and a radiation characteristic having an improved dependency of the color from the spatial angle is to be provided. Further, a simplified method for producing a plurality of light emitting semiconductor chips is to be provided.

According to an embodiment, the light emitting semiconductor chip comprises a chip region with an epitaxial semiconductor layer stack, the epitaxial semiconductor layer stack having an active zone configured to generated electromagnetic radiation of a first wavelength range during operation. For example, the active zone is configured to generate blue light during operation.

According to a further embodiment, the light emitting semiconductor chip comprises a wavelength conversion element converting the electromagnetic radiation of the first wavelength range at least partially into electromagnetic radiation of a second wavelength range. In particular, the first wavelength range is at least partially different from the second wavelength range.

According to a further embodiment of the light emitting semiconductor chip, the wavelength conversion element is arranged on or over a main surface of the chip region. The term “over” indicates in particular that the two elements thus related to each other do not necessarily have to be in direct physical contact. Rather, further elements may be arranged in between them.

According to a further embodiment of the light emitting semiconductor chip, the wavelength conversion element covers only a part of a main surface of the chip region, while a further part of the main surface of the chip region is free of the wavelength conversion element. The part of the main surface of the chip region being free of the wavelength conversion element emits unconverted light of the first wavelength range during operation. The wavelength conversion element emits converted electromagnetic radiation of the second wavelength range during operation. In particular, the light emitting semiconductor chip emits mixed radiation of converted and unconverted electromagnetic radiation during operation. The color locus of the mixed radiation is controlled by the part of the main surface of the chips region being covered by the wavelength conversion element.

According to an embodiment, the light emitting semiconductor chip comprises a chip region comprising an epitaxial semiconductor layer stack with an active zone configured to generate electromagnetic radiation of a first wavelength range during operation, and a wavelength conversion element converting the electromagnetic radiation of the first wavelength range in electromagnetic radiation of a second wavelength range, wherein the wavelength conversion element is arranged on or over a main surface of the chip region, and the wavelength conversion element covers only a part of a main surface of the chip region, while a further part of the main surface of the chip region is free of the wavelength conversion element.

According to a further embodiment of the light emitting semiconductor chip, the wavelength conversion element comprises wavelength converting semiconductor nanocrystals and/or wavelength converting perovskite nanocrystals as wavelength converting materials. In other words, wavelength converting semiconductor nanocrystals and/or wavelength converting perovskite nanocrystals impart the wavelength conversion properties to the wavelength conversion element.

The wavelength converting properties of wavelength converting semiconductor nanocrystals are due to limited dimensions of their functional elements such as a core and a shell.

The wavelength converting semiconductor nanocrystals comprise, for example, a core and a shell, wherein the core and the shell each comprises a semiconductor material or consists of a semiconductor material. The bandgap of the shell is in general adapted by the semiconductor material and the dimension such that the shell absorbs electromagnetic radiation of the first wavelength range. The core of the wavelength converting semiconductor nanocrystal is, in general, adapted by the semiconductor material and the dimensions so that at least a part of the energy absorbed with the electromagnetic radiation of the first wavelength range is reemitted as electromagnetic radiation of the second wavelength range. The core or the core and the shell of a wavelength converting semiconductor nanocrystal has, for example, a diameter between and including 2 Nanometer and 20 Nanometer.

Further, the wavelength converting semiconductor nanocrystal is, for example, enveloped by one or several cover layers. The cover layer is, in particular, configured to protect the core and/or the shell from harmful environmental influences, such as oxygen and/or water leading to an oxidation of the core and/or the shell. Further, the cover layer might be configured to reduce an agglomeration of the wavelength converting semiconductor nanocrystals. For example, the cover layer can comprise or consist of an organic or inorganic material. For example, the cover layer comprises or consists of a glass or a ceramic. In particular, the cover layer comprises or consists of an oxide or a nitride. For example, the cover layer comprises or consists of silica.

A grain of a wavelength converting semiconductor nanocrystals with one or several cover layers might have a diameter between and including 50 Nanometer and 20 Micrometer.

The wavelength converting properties of wavelength converting perovskite nanocrystals are also due to their limited dimensions. In particular, wavelength converting perovskite nanocrystals have a perovskite crystal structure. For example, wavelength converting perovskite nanocrystals are metal halide materials. For example, wavelength converting perovskite nanocrystals comprises or consists of CsPbBr₃ and/or CsPbBrI₂. The wavelength converting perovskite nanocrystal may comprise organic ligands on a surface. For example, the wavelength converting perovskite nanocrystal has a diameter between and including 2 Nanometer and 20 Nanometer.

According to a further embodiment of the light emitting semiconductor chip, the wavelength converting semiconductor nanocrystals and/or the wavelength converting perovskite nanocrystals are comprised by a binder material. The binder material can be an inorganic material or an organic material. For example, an inorganic binder material is an oxide or a nitride. For example, the binder material is formed from the material of the cover layer of the wavelength converting semiconductor nanocrystal.

Due to their small size, the use of wavelength converting semiconductor nanocrystal and/or wavelength converting perovskite materials particularly preferably allows the manufacturing of wavelength conversion elements having small dimensions. The wavelength conversion elements having small dimensions can, in particular, be implemented in a light emitting semiconductor chip with small edge length. For example, the light emitting semiconductor chip has an edge length of at most 10 micrometer, of at most 5 micrometer or of at most 1 micrometer.

According to a further embodiment of the light emitting semiconductor chip, the wavelength conversion element is free of a polymeric matrix material. In particular, the binder is not an organic polymeric matrix material such as a silicone or an epoxy resin.

According to a further embodiment of the light emitting semiconductor chip, the wavelength conversion element has a thickness of at most 5 micrometer, or of at most 1 micrometer. Wavelength conversion elements with a low thickness can, in particular, be achieved by the use of wavelength converting semiconductor nanocrystals and/or wavelength converting perovskite having a small size.

According to a further embodiment, the light emitting semiconductor chip emits mixed electromagnetic radiation of unconverted electromagnetic radiation and converted electromagnetic radiation during operation. In particular, the mixed radiation is white light.

According to a further embodiment of the light emitting semiconductor chip, the wavelength conversion element converts the electromagnetic radiation of the first wavelength range completely into electromagnetic radiation of a second wavelength range. In other words, the degree of the conversion of the electromagnetic radiation from the first wavelength range is as high as possible. It is known for a person skilled in the art that a hundred percent conversion of electromagnetic radiation is only an ideal case.

According to a further embodiment of the light emitting semiconductor chip, the wavelength conversion element comprises at least two parts, one part converting electromagnetic radiation of the first wavelength range into electromagnetic radiation of the second wavelength range and one part converting electromagnetic radiation of the first wavelength range into electromagnetic radiation of a third wavelength range. In particular, the two parts of the wavelength conversion element are arranged laterally and not stacked above each other, seen in top view on the main surface of the chip region. Further, the first wavelength range, the second wavelength range and the third wavelength range are at least partially different from each other.

For example, one part of the wavelength conversion element converts blue light generated in the active zone during operation as electromagnetic radiation of the first wavelength range into green light as electromagnetic radiation of the second wavelength range, preferably completely. The other part of the wavelength conversion element converts, for example, blue light of the active zone into red light as electromagnetic radiation of the third wavelength range, preferably completely. In this case, the light emitting semiconductor chip emits mixed radiation of the first wavelength range, the second wavelength range and the third wavelength range. For example, the light emitting semiconductor chip emits white light consisting of red light of the third wavelength range, green light of the second wavelength range and blue light of the first wavelength range.

The wavelength conversion element can comprise more than two parts, each part converting the electromagnetic radiation of the first wavelength range in a different further wavelength range. In particular, the two or more parts of the wavelength conversion element are arranged laterally and not stacked above each other seen in plan view on the main surface of the chip region. In other words, the two or more parts of the wavelength conversion element cover different areas of the main surface of the chips region, the different areas do not overlap with each other.

According to a further embodiment of the light emitting semiconductor chip, the wavelength conversion element comprises several wavelength converting materials, each wavelength converting material converting the electromagnetic radiation of the first wavelength range into a different other wavelength range. For example, the other wavelength range is in the cyan spectral range, in the green spectral range, in the yellow spectral range or in the red spectral range. With the help of several wavelength converting materials within the wavelength conversion element, the color locus of the light emitted by the light emitting semiconductor chip can be adapted in a predetermined manner. In this embodiment the different wavelength converting materials can be comprised by different parts of the wavelength conversion element being locally separated from each other or can be comprised by some or all parts of the wavelength conversion element.

According to a further embodiment of the light emitting semiconductor chip, an edge region of the main surface is free of the wavelength conversion element. In such a way, a blue appearance at those emission angles further from 90° to the main surface of the chip region can be achieved, if the first wavelength range comprises blue light.

The light emitting semiconductor chip can be manufactured by the method described in the following. Therefore, features and embodiments described in connection with the light emitting semiconductor chip can also be embodied by the method and vice versa.

According to an embodiment of the method for manufacturing a plurality of light emitting semiconductor chips, an epitaxial semiconductor layer sequence with an active layer is provided, the active layer being configured to generate electromagnetic radiation of a first wavelength range during operation. The epitaxial semiconductor layer sequence comprises a plurality of chip regions. In particular, the epitaxial semiconductor layer sequence is provided in the form of a wafer. In other words, the method described herein is, in particular, a method at wafer level, wherein a plurality of light emitting semiconductor chips is manufactured in parallel batch process steps.

According to a further embodiment of the method, wavelength conversion elements are deposited on or over main surfaces of the chip regions. In particular, the wavelength conversion elements convert the electromagnetic radiation of the first wavelength range into electromagnetic radiation of a second wavelength range. In particular, on or over each chip region, one wavelength conversion element is arranged.

According to a further embodiment of the method, the wavelength conversion elements cover only parts of the main surfaces of the chip regions, while further parts of the main surfaces of the chip regions are free of the wavelength conversion element.

In particular, the method for manufacturing a plurality of light emitting semiconductor chips comprises:
providing the epitaxial semiconductor layer sequence with the active layer configured to generate electromagnetic radiation of the first wavelength range during operation, wherein the epitaxial semiconductor layer sequence comprises the plurality of chip regions,
depositing the wavelength conversion elements on or over the main surfaces of the chips regions, wherein
the wavelength conversion elements convert the electromagnetic radiation of the first wavelength range in electromagnetic radiation of the second wavelength range,
the wavelength conversion elements cover only parts of the main surfaces of the chip regions, while further parts of the main surfaces of the chip regions are free of the wavelength conversion elements.

For example, the steps disclosed in the previous paragraph are conducted in the mentioned order.

In order to achieve light emitting semiconductor chips being separated from one another, the compound comprising the epitaxial semiconductor layer sequence and the wavelength conversion elements is separated along separation lines according to an embodiment of the method. In particular, after separation along the separation lines each light emitting semiconductor chip comprises an epitaxial semiconductor layer stack with an active zone and a wavelength conversion element arranged on or over a main surface of the chip region.

According to a further embodiment of the method, depositing the wavelength conversion elements on or over the main surface of the chip regions comprises depositing a wavelength conversion layer completely over a main surface of the epitaxial semiconductor layer sequence. In other words, the wavelength conversion layer is deposited over the whole surface of the epitaxial semiconductor layer sequence. In a further step of this embodiment of the method, the wavelength conversion layer is structured such that the wavelength conversion elements are generated over the main surfaces of the chip regions. The wavelength conversion layer is, for example, deposited by at least one of the following methods: spin-coating, printing, doctor blading.

For the deposition of the wavelength conversion layer a solution comprising a solvent and particles of wavelength converting material such as wavelength converting semiconductor nanocrystals and/or wavelength converting perovskite nanocrystals is provided, for example. The solvent is, for example, an organic solvent such as an alcohol. For example, the solution is embodied in a watery manner having a low viscosity being similar to water.

With the method provided, the wavelength conversion layer can be structured advantageously with frontend processes, such as spin-coating, etching or photolithography. This is in particular possible by using wavelength converting semiconductor nanocrystals and/or wavelength converting perovskite nanocrystals as wavelength materials, since they allow manufacturing of a very thin wavelength conversion layer due to their small size.

For example, the structuring of the wavelength conversion layer comprises a photolithographic method. During the photolithographic method a structured photoresist mask layer is deposited over the wavelength conversion layer and areas that are freely accessible through the mask layer are, for example, removed such that a plurality of conversion elements is generated on or over the main surfaces of the chip regions.

According to a further embodiment of the method, the wavelength conversion elements are deposited in a structured manner on or over the main surface of the chip regions. In other words, during this embodiment of the method the wavelength conversion elements are deposited directly in a structured manner, in contrast to the embodiment of the method explained above wherein, in a first step, the wavelength conversion layer is deposited over the whole main surface of the epitaxial semiconductor layer sequence and structured subsequently for the formation of a plurality of wavelength conversion elements. For example, the wavelength conversion elements are deposited directly in a structured manner on or over the main surfaces of the chip regions by jetting. Also, a solution from a solvent and wavelength nanocrystals as described above can be jetted in order to achieve wavelength conversion elements.

According to a further embodiment of the method, material of the wavelength conversion element is removed such that the part of the main surface of the chip region covered by the wavelength conversion element is decreased. For example, the material of the wavelength conversion element is removed by laser ablation. For example, the material of the wavelength conversion element is removed strip-wise. In particular, material of several wavelength conversion elements is removed subsequently one after the other in a serial manner.

In particular, the material is removed from the wavelength conversion element after measurement of a color locus of the electromagnetic radiation emitted from the chip region and the wavelength conversion element on or over the main surface of the chip region. In such a way the color locus of the light emitted from the light emitting semiconductor chips can be adapted in a predetermined manner on wafer level. In this way, light emitting semiconductor chips can be achieved having an improved color locus and color over angle of the converted light. In particular, it is possible to provide a plurality of light emitting semiconductor chips emitting light with a color locus that are very similar to each other.

In particular, the color locus of the plurality of light emitting semiconductor chips is arranged within a 3 or a 5 step MacAdam's ellipse. This reduces or prevents a sorting process of the semiconductor chips after separation and therefore simplifies the manufacturing process.

In particular, with the provided method, very dense wavelength conversion elements having a high density of wavelength converting material can be achieved. A well-controlled and small thickness of the wavelength conversion element can be achieved in particular by using frontend-style processes such as spin-coating. Also, the structuring of the wavelength conversion layer and therefore the geometry of the wavelength conversion elements on or over the chip regions can be defined with very high accuracy due to the use of frontend-style processes, such as photolithographic techniques, etching or strip-wise trimming by a laser.

Further details and improvements of the light emitting semiconductor chip and the method for manufacturing a plurality of light emitting semiconductor chips are described in the following in connection with the Figures.

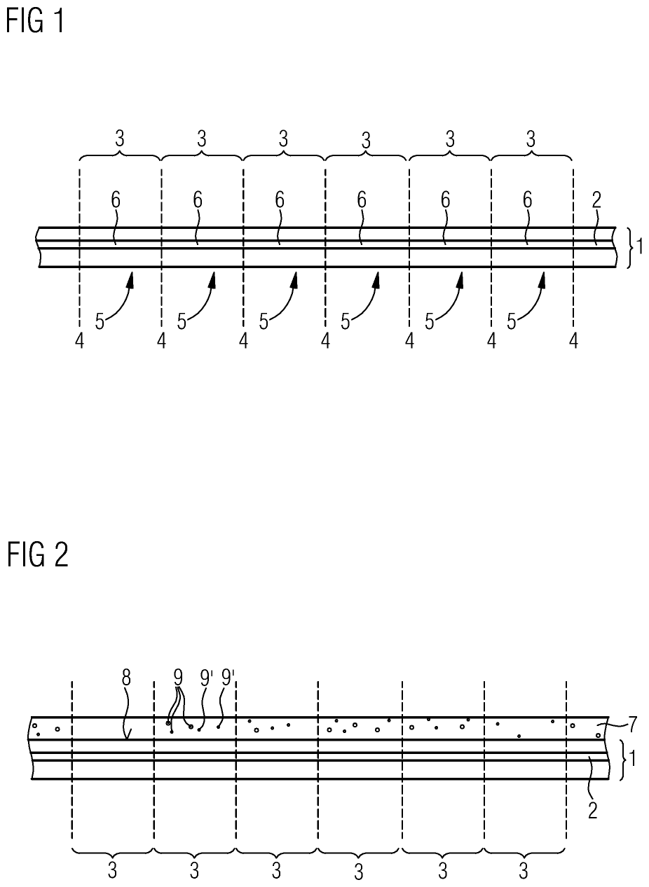

FIGS. 1 to 6 show schematic views of stages of a method for manufacturing a plurality of light emitting semiconductor chips according to an exemplary embodiment.

FIG. 7 shows a schematic view of a stage of a method for manufacturing a plurality of light emitting semiconductor chips according to a further exemplary embodiment.

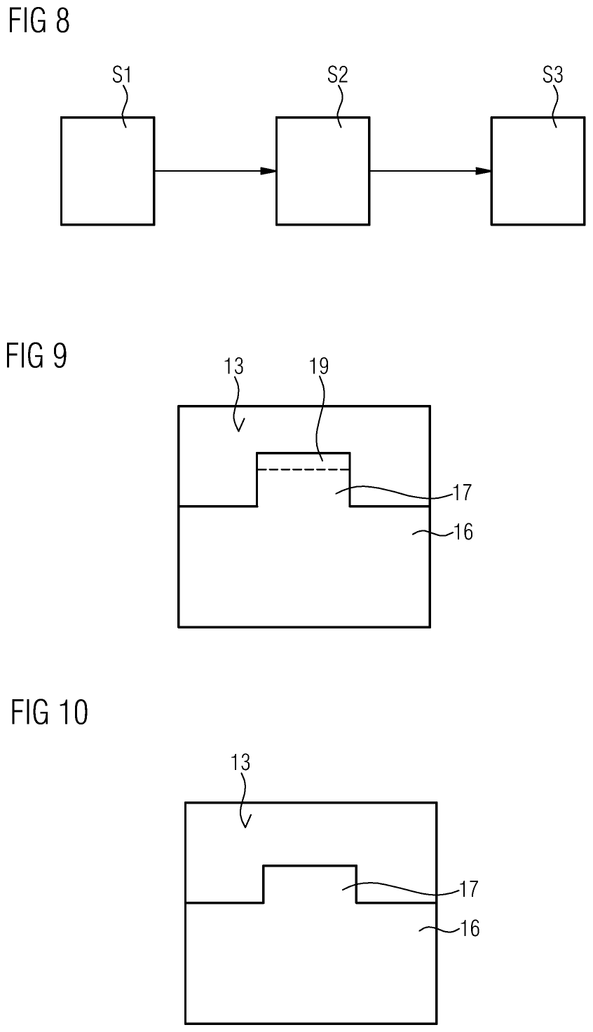

FIG. 8 shows a flow diagram with steps of a method for manufacturing a plurality of light emitting semiconductor chips according to a further exemplary embodiment.

FIGS. 9 to 11 illustrate the method according to the exemplary embodiment of FIG. 8 further.

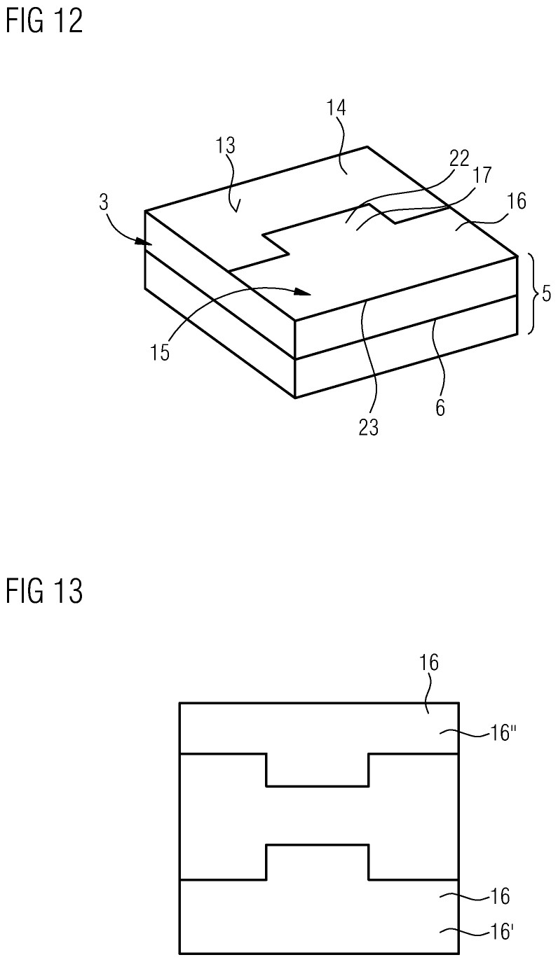

FIGS. 12 to 15 show schematic views of light emitting semiconductor chips according to several embodiments.

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

During the method according to the exemplary embodiment of FIGS. 1 to 6, an epitaxial semiconductor layer sequence 1 with an active layer 2 configured to generated electromagnetic radiation of a first wavelength range during operation is provided (FIG. 1). The epitaxial semiconductor layer sequence 1 comprises a plurality of chip regions 3 separated from each other by separation lines 4. Each chip region 3 comprises an epitaxial semiconductor layer stack 5, which is separated from the directly adjacent epitaxial semiconductor layer 5 stack by a separation trench (not shown). Each epitaxial semiconductor layer stack 5 comprises an active zone 6 being part of the active layer 2.

In a further step, a wavelength conversion layer 7 is deposited over a whole main surface 8 of the epitaxial semiconductor layer sequence 1 (FIG. 2). The wavelength conversion layer 7 comprises, for example, wavelength converting semiconductor nanocrystals 9 or wavelength converting perovskite nanocrystals 9′. For example, the wavelength converting layer 7 is deposited on or over the main surface 8 of the epitaxial semiconductor layer sequence by spin-coating.

During spin-coating a liquid solution 10 comprising the wavelength conversion material such as the wavelength converting semiconductor nanocrystals 9 or the wavelength converting perovskite nanocrystals 9′ is deposited on or over the main surface 8 epitaxial semiconductor layer sequence 1 and rotated such that a thin layer of the solution 10 is generated on or over the whole main surface 8 of the epitaxial semiconductor layer sequence 1 (not shown). Besides the wavelength converting material provided in the form of particles, the solution 10 comprises a solvent 11, for example an organic solvent such as an alcohol. After deposition of the wavelength conversion material, the solvent 11 is removed, for example by drying.

By spin-coating, very well defined wavelength conversion layers 7 can be achieved. This enhances the adjustment of the color locus and the color of angle of the finished light emitting semiconductor chips. Particularly, the wavelength conversion layer 7 has a very small thickness of at most 5 micrometer or of at most 1 micrometer.

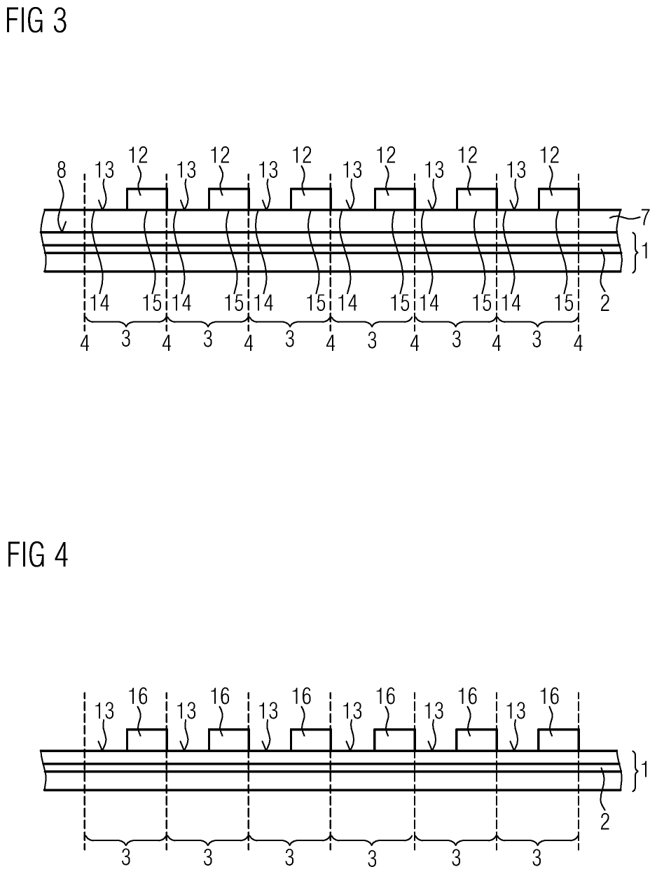

In a further step, a structured photoresist mask layer 12 is deposited on or over the main surface 8 of the epitaxial semiconductor layer sequence 1 (FIG. 3). The photoresist mask layer 12 is structured in a way that a part 15 of a main surface 13 of each chip region 3 is covered by the photoresist mask layer 12, while a further part 14 of the main surface 13 of each chip region 3 is freely accessible.

In a further step, the wavelength converting material of the wavelength conversion layer 7 is removed in the parts 14, where it is freely accessible. For example, the wavelength converting material is removed by etching. In such a way, a wavelength conversion element 16 is formed on or over a main surface 13 of each chip region 3. (FIG. 4).

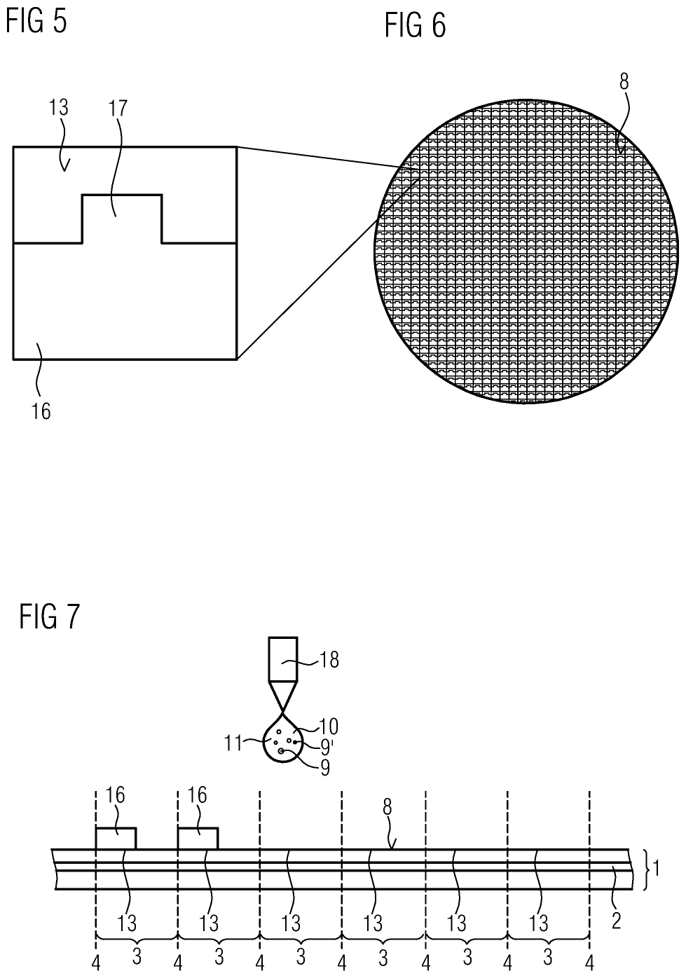

FIG. 6 shows a plan view on the main surface 8 of the semiconductor layer sequence 1 covered partially with the wavelength conversion elements 16. The main surface 13 of each chip region 3 is partially covered with a wavelength conversion element 16. A plan view on a main surface 13 of a chip region 3 is exemplarily shown in FIG. 5.

As can be seen in FIG. 5, a part 15 of the main surface 13 of the chip region 3 is covered with the wavelength conversion element 16, while a further part 14 of the main surface 13 of the chip region 3 is free of the wavelength conversion element 16. At present, a wavelength conversion element 16 converts electromagnetic radiation generated in the active zone 6, for example blue light, into yellow light.

Particularly, the wavelength conversion element 16 has in plan view a rectangular part 17 protruding in the part of the main surface 13 of the chip region 3 being free of the wavelength conversion element 16.

In contrast to the method according to exemplary embodiment of FIGS. 1 to 6, wherein a wavelength conversion layer 7 is arranged over the whole main surface 8 of the epitaxial semiconductor layer sequence 1 and structured in a subsequent process step, the wavelength conversion layer 7 is deposited directly on or over the main surface 8 of the epitaxial semiconductor layer sequence 1 in a structured manner during the method according to the exemplary embodiment of FIG. 7. This can be done, for example, by jetting a liquid solution of wavelength converting nanocrystals 9, 9′ in a solvent 11.

During jetting, the solution 10 of the wavelength converting nanocrystals such as wavelength converting semiconductor nanocrystals 9 and/or wavelength converting perovskite nanocrystals 9′, is subsequently deposited by a nozzle 18 by scanning over the main surface 8 of the epitaxial semiconductor layer sequence 1. In particular, the nozzle 18 scans over the main surface 8 of the epitaxial semiconductor layer sequence 1 and deposits a predetermined amount of the wavelength converting solution on each main surface 13 of the chip region 3.

During the method according to the exemplary embodiment of FIGS. 8 to 11, wavelength conversion elements 16 are deposited on or over main surfaces 13 of a plurality of chip regions 3 in a first step S1 as, for example, already described in connection with the exemplary embodiment of FIGS. 1 to 6 or in connection with the exemplary embodiment of FIG. 7.

For example, the epitaxial semiconductor layer sequence 1 is currently not separated in single light emitting semiconductor chips. However, it is possible to electrically contact the epitaxial semiconductor layer stacks 5 of the epitaxial semiconductor layer sequence 1 individually such that mixed light of unconverted electromagnetic radiation of the first wavelength range and converted electromagnetic radiation of the first wavelength range is emitting through each main surface 13 of each chip region 3.

In a further step S2, the color locus of the mixed light of the unconverted electromagnetic radiation emitted from the free part of the main surface 13 of the chip region 3 and the converted region emitted by the wavelength conversion element 16 over a part 15 of the main surface 13 of the chip region 3 is measured. Then, if necessary, material of the wavelength conversion element 16 is removed in further step S3, for example by ablation with a laser, such that the part 15 of the main surface 13 of the chip region 3 covered by the wavelength conversion element 16 is decreased. If necessary, steps S2 and S3 can be repeated until a predetermined color locus of the mixed light is achieved.

For example, the material of the wavelength conversion element 16 is removed strip-wise during process step S2. For example, a strip 19 of the rectangular protrusion 17 can be removed as shown in FIGS. 9 and 10. Then, the wavelength conversion element 16 covers less area of the main surface 13 of the chip region 3 such that the part of the converted electromagnetic radiation of the mixed light is reduced and the color locus of the mixed light is amended.

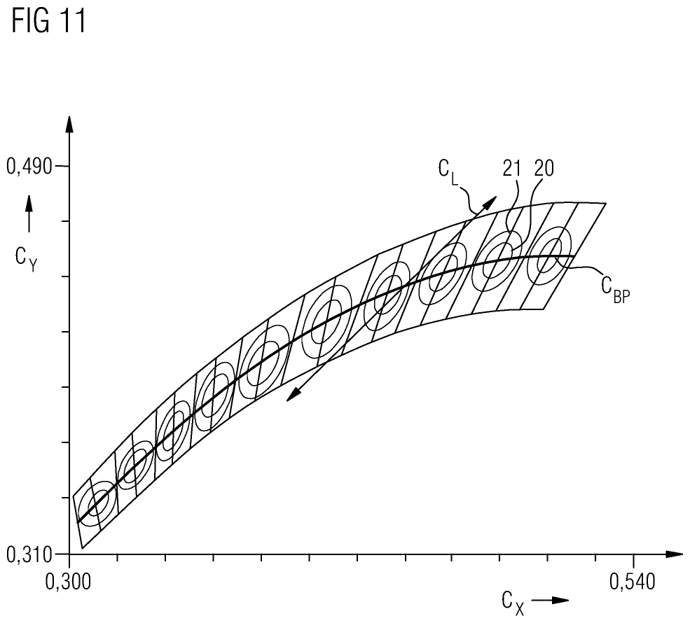

FIG. 11 shows a diagram of chromaticity coordinates Cx and Cy of mixed light emitted by light emitting semiconductor chips, the mixed light comprising unconverted light of an active zone 6 as well as converted light from a wavelength conversion element 16. Around points of the black body curve C_{BP} 3step MacAdam's ellipses 20 and 5step MacAdam's ellipses are inserted in FIG. 11. Light emitting semiconductor chips can be sorted such that the color locus of their light is located within a 3step Mc MacAdam's or in a 5step Mc MacAdam's in order to provide a plurality of light emitting semiconductor chips to the customer producing very similar light (binning).

When removing material from the wavelength conversion element 16 as explained in connection with FIGS. 8 to 10, the color locus of the light emitting semiconductor chips are moved along a load line C_{L} for a particular mixture of wavelength conversion material.

The light emitting semiconductor chip according to the exemplary embodiment of FIG. 12 can be produced with a method as described, for example, in connection with the foregoing Figures.

The light emitting semiconductor chip according to FIG. 12 comprises a chip region 3 with an epitaxial semiconductor layer stack 5. The epitaxial semiconductor layer stack 5 comprises an active zone 6 generating electromagnetic radiation of a first wavelength range, at present blue light, during operation. Further, the light emitting semiconductor chip according to FIG. 12 comprises a wavelength conversion element 16, which covers a part 15 of a main surface 13 of the chip region 3. A further part 14 of the main surface 13 of the chip region 3 is freely accessible such that unconverted blue light is emitted during operation from this part 14 of the main surface 13. The light emitting semiconductor chip emits mixed light during operation, the mixed light comprises unconverted blue light of the active zone 6 and yellow light converted by the wavelength conversion element 16.

The wavelength conversion element 16 comprises at present a rectangular protrusion 17 arranged on or over a central part 22 of the main surface 13 of the chip region 3. The wavelength conversion element 16 extends from an edge region 23 of the chip region 3 to the central part 22 of the main surface 13 of the chip region 3.

In contrast to the light emitting semiconductor chip of FIG. 12, the light emitting semiconductor chip of FIG. 13 has a wavelength conversion element 16 comprising two parts 16′, 16″ being different from each other. In particular, the wavelength conversion element 16 of the light emitting semiconductor chip of FIG. 13 comprises a part 16′ converting blue light of the active zone 6 completely into red light, while a further part 16″ of the wavelength conversion elements 16 converts blue light of the active zone 6 completely into green light. The light emitting semiconductor chip of the exemplary embodiment of FIG. 13 emits mixed light of blue unconverted light, green converted light and red converted light.

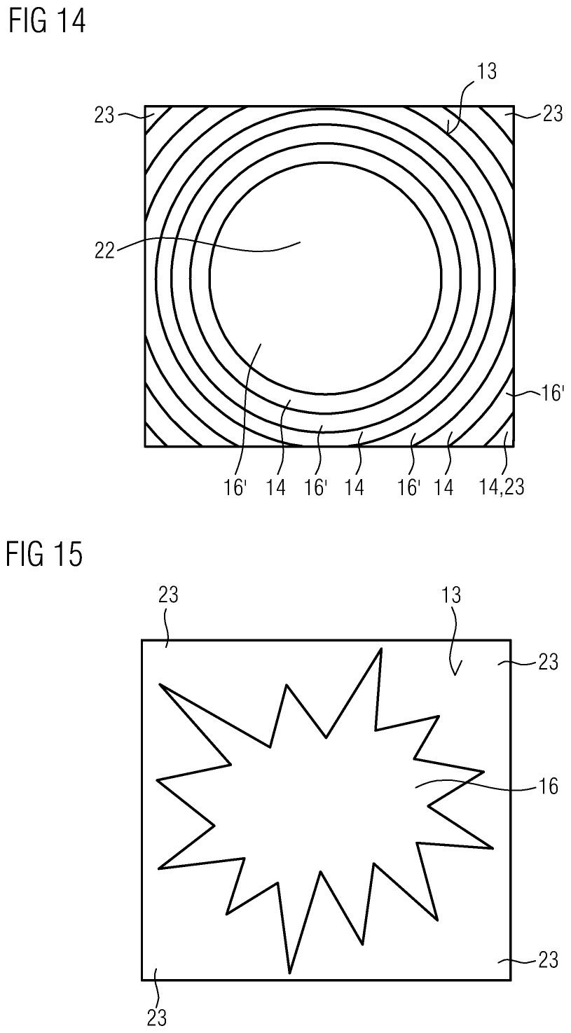

FIG. 14 shows a plan view on a main surface 13 of a chip region 3 of a light emitting semiconductor chip according to a further exemplary embodiment. The wavelength conversion element 16 of the light emitting semiconductor chip of the exemplary embodiment of FIG. 14 comprises several parts 16′ having a circular shape. Over a central part 22 of the main surface 13 of the chip region 3 a circular part 16′ of the wavelength conversion element 16 is arranged followed by concentric arranged rings 16′ of the wavelength conversion element 16. Between the concentric rings 16′ of the wavelength conversion element 16 ring-shaped parts 14 of the main surface 13 of the chip region 3 are not covered by the wavelength conversion element 16 and freely accessible. The wavelength conversion element 16 converts blue light of the active zone into red light. In particular, edge regions 23 of the main surface 13 of the chip regions 3 are free of wavelength conversion element.

The light emitting semiconductor chip according to the exemplary embodiment of FIG. 15 comprises a wavelength conversion element 16 having an irregular star-shaped form in plan view. Also, edge regions 23 of the main surface 13 of the chip region 3 are free of the wavelength conversion element 16.

The features and exemplary embodiments described in connection with the Figures can be combined with each other according to further exemplary embodiments, even if not all combinations are explicitly described. Furthermore, the exemplary embodiments described in connection with the Figures may alternatively or additionally have further features according to the description in the general part.

The invention is not limited to the description of the embodiments. Rather, the invention comprises each new feature as well as each combination of features, particularly each combination of features of the claims, even if the feature or the combination of features itself is not explicitly given in the claims or embodiments.

### REFERENCES

1 epitaxial semiconductor layer sequence
2 active layer
3 chip region
4 separation line
epitaxial semiconductor layer stack
6 active zone
7 wavelength conversion layer
8 main surface of the epitaxial semiconductor layer sequence
9 wavelength converting semiconductor nanocrystal
9′ wavelength converting perovskite nanocrystal
10 solution
11 solvent
12 photoresist mask layer
3 main surface of each chip region
14 uncovered part of the main surface of the chip region
15 covered part of the main surface of the chip region
16 wavelength conversion element
17 rectangular part of the wavelength conversion element
18 nozzle
19 strip
20 3step MacAdam's ellipse
21 5step MacAdam's ellipse
22 central part of the main surface of the chip region
23 edge region of the chip region
S1, S2, S3 process steps
C_{BP} black body curve C_{BP}
C_{L} load line C_{L}

1. Light emitting semiconductor chip comprising:
a chip region comprising an epitaxial semiconductor layer stack with an active zone configured to generate electromagnetic radiation of a first wavelength range during operation,
a wavelength conversion element converting the electromagnetic radiation of the first wavelength range in electromagnetic radiation of a second wavelength range, wherein
the wavelength conversion element is arranged on or over a main surface of the chip region, and
the wavelength conversion element covers only a part of the main surface of the chip region, while a further part of the main surface of the chip region is free of the wavelength conversion element.

2. Light emitting semiconductor chip according to claim 1, wherein the wavelength conversion element comprises wavelength converting semiconductor nanocrystals and/or wavelength converting perovskite nanocrystals as wavelength converting materials.

3. Light emitting semiconductor chip according to claim 2, wherein the wavelength converting semiconductor nanocrystals and/or the wavelength converting perovskite nanocrystals are comprised by a binder material.

4. Light emitting semiconductor chip according to claim 1, wherein the wavelength conversion element is free of an organic polymeric matrix material.

5. Light emitting semiconductor chip according to claim 1, wherein the wavelength conversion element has a thickness of at most 5 micrometer.

6. Light emitting semiconductor chip according to claim 1 emitting mixed electromagnetic radiation of unconverted electromagnetic radiation and converted electromagnetic radiation during operation.

7. Light emitting semiconductor chip according to claim 1, wherein the wavelength conversion element converts the electromagnetic radiation of the first wavelength range completely in electromagnetic radiation of a second wavelength range.

8. Light emitting semiconductor chip according to claim 1, wherein
the wavelength conversion element comprises at least two parts, one part converting electromagnetic radiation of the first wavelength range in electromagnetic radiation of the second wavelength range and one part converting electromagnetic radiation of the first wavelength range in electromagnetic radiation of a third wavelength range
the two parts being arranged laterally.

9. Light emitting semiconductor chip according to claim 1, wherein the wavelength conversion element comprises several wavelength converting materials, each wavelength converting material converting the electromagnetic radiation of the first wavelength range in a different other wavelength range.

10. Light emitting semiconductor chip according to claim 1,
wherein an edge region of the main surface is free of the wavelength conversion element.

11. Method for manufacturing a plurality of light emitting semiconductor chips comprising:
providing an epitaxial semiconductor layer sequence with an active layer configured to generate electromagnetic radiation of a first wavelength range during operation, wherein the epitaxial semiconductor layer sequence comprises a plurality of chip regions,
depositing wavelength conversion elements on or over main surfaces of the chips regions, wherein
the wavelength conversion elements convert the electromagnetic radiation of the first wavelength range in electromagnetic radiation of a second wavelength range,
the wavelength conversion elements cover only parts of the main surfaces of the chip regions, while further parts of the main surfaces of the chip regions are free of the wavelength conversion elements.

12. Method according to claim 11, wherein depositing the wavelength conversion elements on or over the main surface of the chip regions comprises:
depositing a wavelength conversion layer completely over a main surface of the epitaxial semiconductor layer sequence, and
structuring the wavelength conversion layer such that the wavelength conversion elements are generated over the main surfaces of the chip regions.

13. Method according to claim 12, wherein the wavelength conversion layer is deposited by at least one of the following methods: spin-coating, printing, doctor blading.

14. Method according to claim 12, wherein structuring the wavelength conversion layer comprises a photolithographic method.

15. Method according to claim 11, wherein the wavelength conversion elements are deposited in a structured manner on or over the main surfaces of the chip regions.

16. Method according to claim 11, wherein material of the wavelength conversion element is removed such that the part of the main surface of the chip region covered by the wavelength conversion element is decreased.

17. Method according to claim 16, wherein the material is removed from the wavelength conversion element after measurement of a color locus of the electromagnetic radiation emitted from the chip region and the conversion element on the main surface of the chip region.
